(19) United States
(12) Patent Application Publication
(10) Pub. No.: US 2014/0154539 A1
(43) Pub. Date: Jun. 5, 2014

(54) MODULE FOR SECURING ENERGY STORAGE CELLS

(71) Applicant: CATERPILLAR INC., Peoria, IL (US)

(72) Inventors: Wellington Y. Kwok, Dunlap, IL (US); Keith E. Dixler, Peoria, IL (US); Shane A. Mockbee, Washington, IL (US)

(73) Assignee: Caterpillar Inc., Peoria, IL (US)

(21) Appl. No.: 13/705,219

(22) Filed: Dec. 5, 2012

(51) Int. Cl. H05K 5/02; H01M 10/50

(52) U.S. Cl. CPC H05K 5/0217; H01M 10/503
USPC 429/82; 429/99; 174/535

(57) ABSTRACT

The disclosure relates to packaging of an energy storage module containing a plurality of storage cells for use in mobile and stationary power generation. The storage cells are pressed into a block of thermally conductive material in order to manage the temperature of the cells. The storage cells are secured between a clamping plate and a chassis. The resulting package is suitable for use in heavy duty applications.

### TECHNICAL FIELD

The present disclosure relates to a module for securing energy storage cells, and more particularly, a module intended for mobile equipment.

### BACKGROUND

Energy storage modules are increasingly used in mobile and stationary applications. Uses include hybrid and electric drive vehicles, as well as stationary power generation. The modules usually contain battery or ultracapacitor cells as a way of storing electrical energy for long periods of time, and/or rapidly charging or discharging as needed. The charge/discharge process quickly generates a large amount of heat, which should be managed. Also, the performance and life of the cells depends upon their temperature. Therefore, the steady state temperature of the cells should be managed.

A further requirement of the energy storage module is that it is capable of operation when exposed to harsh environments. Shock and vibration are problematic when packaging energy storage cells into an energy storage module. The cells should be packaged such that they are not allowed to move rotationally, radially, or axially. Such movement can break inter-cell connections or wear through the protective case of the cell. The energy storage module should protect against shock and vibration while still managing thermal issues.

Excess heat or a manufacturing defect can lead to high levels of heat in a cell which can then cause the destruction of the cell, known as thermal runaway. Destruction of a cell can cause heat damage to adjacent cells which can in turn cause destruction of one or more of the adjacent cells. This is known as cell propagation. Effective thermal management of the energy storage module can prevent thermal runaway and cell propagation.

Mobile applications require secure packaging of an energy storage module due to the shock and vibration introduced by movement of the vehicle over terrain. Automotive applications require a certain amount of protection against shock and vibration. However, heavy duty applications such as mining and construction require an even higher amount of protection.

Stationary applications also require secure packaging of the energy storage module, as the equipment using the energy storage module may be shipped to its location of use. This location can be remote or particularly harsh. Modes of shipping include truck, rail, ship, or even air drop.

Patent application US20120121949 to Eberhard et al. describes a vehicle battery module for use in an electric vehicle that includes insulation or phase change material for thermal management. Eberhard, however, describes a battery cell with terminals on opposite ends. Therefore, the connection and packaging method disclosed does not meet the requirements for protection against shock and vibration in heavy duty applications.

### SUMMARY OF THE INVENTION

In one aspect of the present disclosure, an energy storage module for securing a matrix of storage cells is disclosed. The energy storage module comprises a generally planar chassis and a plurality of generally cylindrical storage cells. The generally cylindrical storage cells have a terminal end, a non-terminal end, and two connection terminals located on said terminal end. The energy storage module further comprises a block of thermally conductive material having an array of generally cylindrical voids configured to accept said storage cells, and a generally planar clamping plate having a matrix of apertures configured to accept said connection terminals. The storage cells are securely located between said clamping plate on said terminal end and said chassis on said non-terminal end.

In another aspect of the present disclosure, an energy storage unit is disclosed. The energy storage unit comprises a housing including a housing top; a housing bottom, and a housing side. The energy storage unit further includes an energy storage module comprising a generally planar chassis and a plurality of generally cylindrical storage cells. The generally cylindrical storage cells have a terminal end, a non-terminal end, and two connection terminals located on said terminal end. The energy storage module further comprises a block of thermally conductive material having an array of generally cylindrical voids configured to accept said storage cells, and a generally planar clamping plate having a matrix of apertures configured to accept said connection terminals. The storage cells are securely located between said clamping plate on said terminal end and said chassis on said non-terminal end. The chassis of energy storage module is secured to the housing.

### BRIEF DESCRIPTION OF THE DRAWINGS

FIG. 1: Energy storage module side view

FIG. 2: Cell detail

FIG. 3: Energy storage module connections (overhead)

FIG. 4: Active cooling

FIG. 5: Side view of chassis, sheet metal w/dimples

FIG. 6: Dimple detail

FIG. 7: Clamping plate

FIG. 8: Overhead view of stacked package

FIG. 9: Overhead view of horizontal package

### DETAILED DESCRIPTION

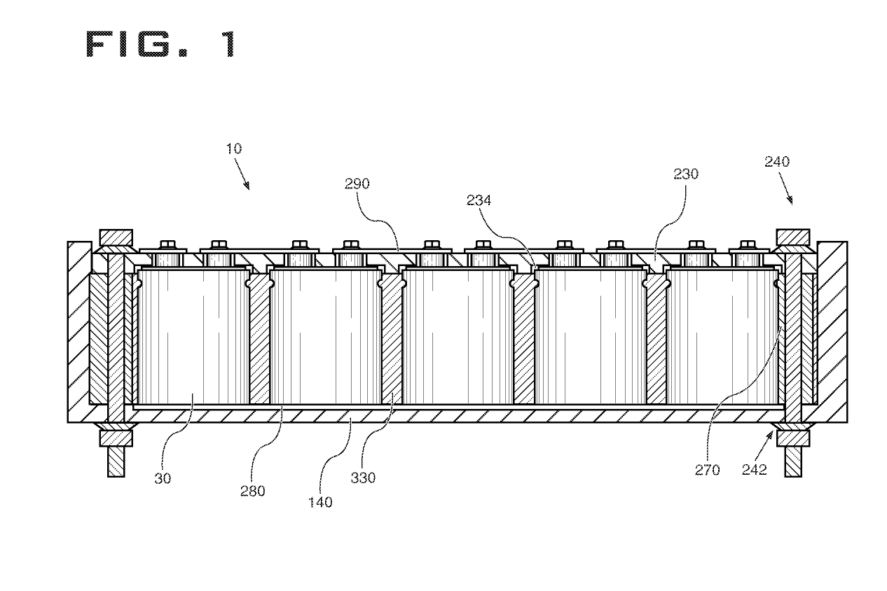

The present disclosure relates to an energy storage module 10 as shown in FIG. 1. The energy storage module 10 secures energy storage cells 30 in a manner suitable for use in harsh environments or heavy duty mobile applications. The energy storage cells 30 could be battery cells or capacitors, particularly ultracapacitors.

Energy storage packages are commonly used in electric drive vehicles, hybrid vehicles, and stationary power generators. In electric drive applications, the energy storage package stores energy from deceleration and provides power for traction motors in order to propel a vehicle. In hybrid applications, the energy storage package stores energy from deceleration and augments an engine in providing power in order to propel a vehicle. In stationary power generator applications, the energy storage package can be used to augment the primary engine and generator. Large amounts of power are charged to and discharged from the energy storage package in these applications. As the life and performance of the energy storage cells 30 is dependent on temperature, it is important to provide cooling for the cells.

The storage cells 30 themselves are either a battery or a capacitor. In the case of a battery, voltage of an individual cell will vary between 1.2 V and 3.4 V depending on battery chemistry. Many battery cells are connected in series in order to achieve an energy storage package with enough voltage to supply the higher voltage required in a vehicle propulsion system or stationary power application. This system voltage is typically 300-600 V, but can be as high as 3300 V in high power applications.

The storage cell 30 may alternatively be a capacitor. Examples include electrolytic capacitors, supercapacitors, and ultracapacitors. Due to their high energy density, electric double-layer capacitors (EDLC) are typically used. EDLCs are commonly known as ultracapacitors. The individual ultracapacitor cells are typically several hundred Farads and have a voltage capacity of 2.5 V. Power capacity varies, but is approximately 40 W in steady-state and up to 180 W peak Like the battery cells, many ultracapacitor cells are connected in series in order to achieve an energy storage package with enough voltage to supply the higher voltage required in a vehicle propulsion system or stationary power application.

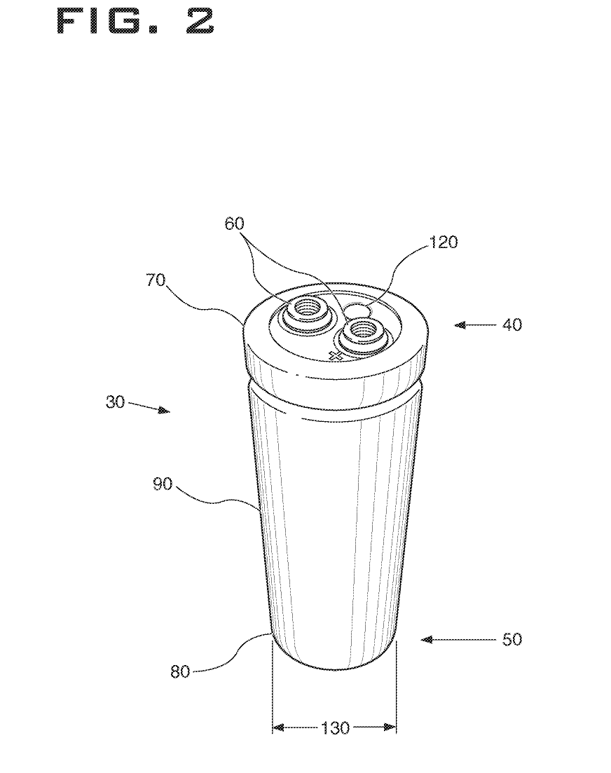

Referring to FIG. 2, the storage cells 30 are generally cylindrical in shape with a diameter 130. The surface of the cylinder is composed of a case 90. The terminal end 40 and non-terminal end 50 of the cylinder is formed by a terminal end cap 70 and a non-terminal end cap 80. Other external features of the storage cell 30 are the connection terminals 60 and a vent 120. The connection terminals 60 serve to electrically connect the cell between the internal cathode and anode and an external electrical circuit. The connection terminals 60 also provide a means for mechanically connecting to an external circuit. The connection terminals 60 may include a threaded hole, threaded post, a press-fit post, or the like.

The vent 120 serves to allow gases to escape the cell in the event of an electrical short of or a thermal failure. Gases escaping through the vent 120 prevent the case 90 from bursting during such a failure.

As stated above, storage cells 30 are typically connected in series in order to meet the voltage and power required in a vehicle propulsion system or stationary power application. This requires a physical package that can accommodate from dozens to hundreds of storage cells 30. In order to achieve the power density required from the package, storage cells 30 are typically packaged in a matrix with their axes aligned physically in parallel. Such an efficient package helps to achieve a high energy density. The package should properly locate the cells, protect them from the environment, and provide adequate thermal management.

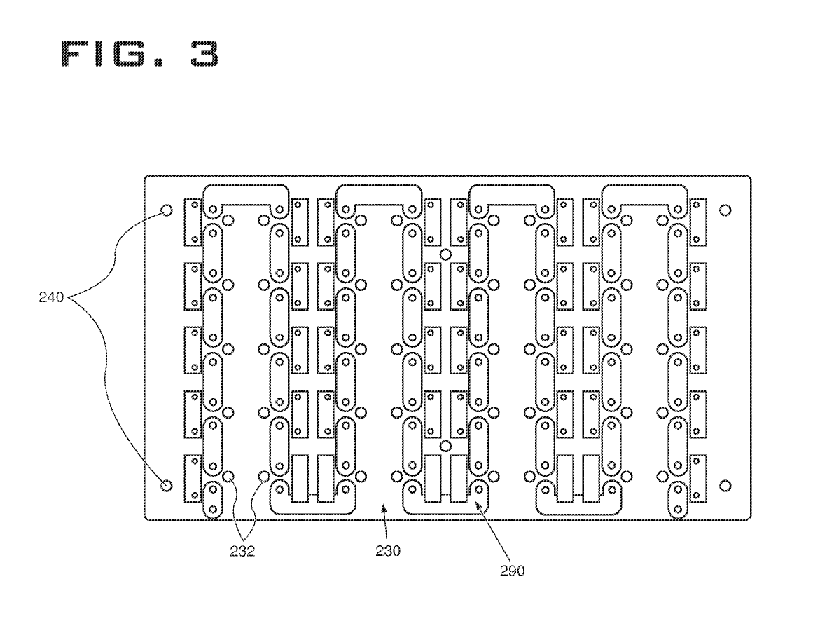

As shown in FIG. 3, storage cells 30 are connected in series by connecting the anode of one to the cathode of another and so on until the number of required series storage cells 30 is reached. Connection between cells is achieved by means of a conductive bus bar 290. Alternatively a printed circuit board with very thick conductive traces can be used that includes provisions for connecting to the storage cells 30. The printed circuit board may also mount components related to cell monitoring or balancing.

Although the bus bars 290 connect all storage cells 30 together, they are not used to secure the storage cells 30 within the module. The internal structure around the connection terminals 60 functions primarily as an electrical connection and is poorly suited for securing the cells against shock or vibration. According to SAE J2289 §5.1.2, “Although electrical cables and inter-cell connections (e.g., bus bars, etc.) may seem to provide some form of retention and restraint of modules in relation with one another, this is not considered to be a part of an acceptable retention system that provides restraint in normal and some safety critical situations.”

The performance of storage cells 30 is dependent on temperature. In the case of a battery, the charge capacity, internal resistance, and operating life degrades with increasing temperature. In the case of an ultracapacitor, the capacitance, internal resistance, and operating life degrade with increasing temperature. Such storage cells 30 generate a considerable amount of heat during charging and discharging and this heat should be managed in some manner in order to preserve performance. Ambient temperature can also cause increase the temperature of the storage cell 30.

It should also be appreciated that since many storage cells 30 are electrically connected in series, the performance of the entire series network could be limited by the performance of the weakest cell. It should therefore be appreciated that all storage cells 30 should be maintained at approximately the same temperature.

One way to control the temperature of the storage cells 30 is by surrounding them in a thermally conductive material 310. The thermally conductive material 310 would serve to mechanically locate the storage cells 30 as well as conducting heat away from the storage cells 30. The thermally conductive material 310 could be foam reinforced with fiberglass, a polymer, a graphite material.

The thermally conductive material 310 could be a phase change material (PCM) 320. The PCM 320 is capable of temporarily storing heat from the storage cells 30 as latent heat. Such a material is described in U.S. Pat. No. 6,468,689 to Al-Hallaj et al of Chicago, Ill.

The thermally conductive material 310 is to be formed into a block 330. A matrix of generally cylindrical voids 340 is formed into the block in order to accept the storage cells 30. The spacing of the rows and columns of the matrix is such that the gap is small enough to allow for high energy density of the module while large enough to allow proper heat conduction away from the storage cells 30.

The cylindrical voids 340 are sized so that the storage cells 30 can be inserted in a press-fit relationship. A press-fit ensures that a) there is enough contact to ensure thermal conduction from the storage cell 30 to the thermally conductive material 310 and b) that the storage cell 30 is secured from motion in the radial direction.

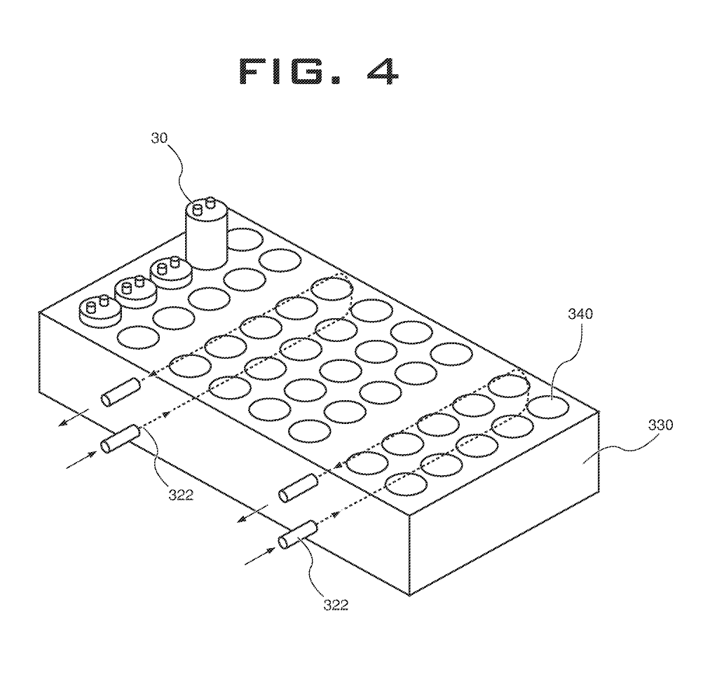

In addition the passive cooling provided by the block 330 of PCM 320, an active cooling loop 322 could be incorporated. Refer to FIG. 4. Passive cooling is considered in this context to be the cooling effect provided by the phase change in the PCM 320. An active cooling loop 322 is to be provided such that a heat transfer fluid can be circulated through the active cooling loop 322 and circulate through the block 330 of PCM 320. The active cooling loop 322 could be used in combination with a pump and heat exchanger as is known in the art. The active cooling loop 322 could for instance be formed by a pipe made of thermally-conductive metal such as copper. Efforts should be made to secure the active cooling loop 322 in the graphite material of the PCM 320 while the graphite material is compressed. A supporting structure, such as a rack or standoffs could be incorporated either inside or outside the graphite material during the manufacturing process. In addition, a supporting medium 324 within the active cooling loop 322 may be needed to keep the active cooling loop 322 from being deformed or crushed during the manufacturing process. The supporting medium 324 would need to be capable of removal after the manufacturing process in order for the heat transfer fluid to be able to flow through the active cooling loop 322. Examples of suitable supporting medium 324 could be sand, paraffin wax (melted and removed afterwards), or an incompressible fluid such as water or oil. The open ends of the active cooling loop 322 would need to be blocked during manufacturing in order to retain the supporting medium 324.

A generally planar chassis 140 provides the foundation for an energy storage module 10 shown in FIG. 1. The chassis 140 could be metal, composite, or other suitable stiff material. A chassis 140 made of metal offers the additional property of heat conduction. A major function of the chassis 140 is to provide support for the storage cells 30 and the block 330 of thermally conductive material 310. Storage cells 30 are supported by the chassis 140 on their non-terminal end cap 80. As is common in the art, the chassis 140 may have various provisions for fasteners and stand-offs for attaching components to the chassis 140 or attaching the chassis 140 to another structure. In addition, the chassis 140 may have at least one vertical portion along at least one edge for attaching the chassis 140 to a vertical surface. The vertical portion may be integral to the chassis 140 or may be a separate structure that is then bolted to the chassis 140.

The chassis 140 includes an element for accepting at least one fastener 240, which functions to secure the clamping plate 230 to the chassis 140. The element could be a blind hole, a through hole, or a weld nut. The blind hole or through hole could be tapped for threads. A threaded nut could also be used to accept the fastener 240.

As shown in FIG. 1, the chassis 140 could also form a portion of a housing 150.

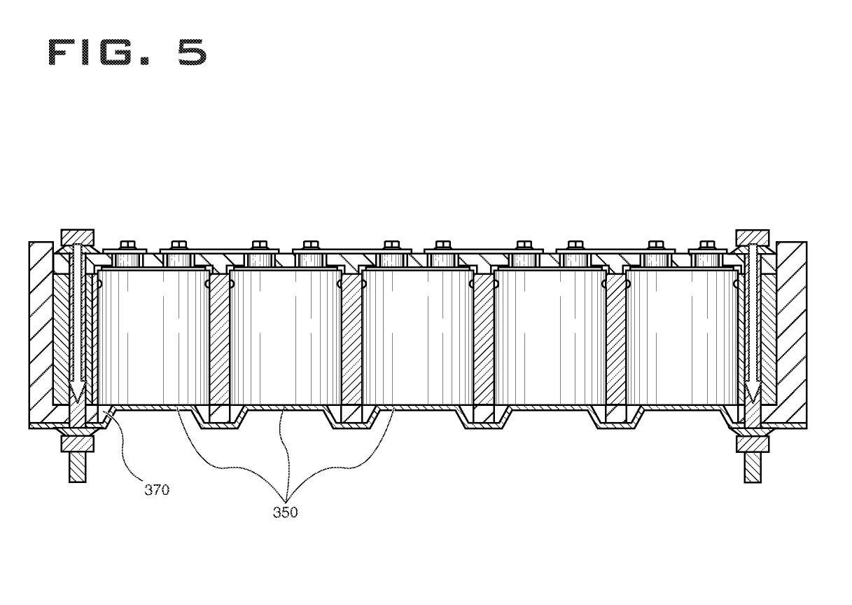

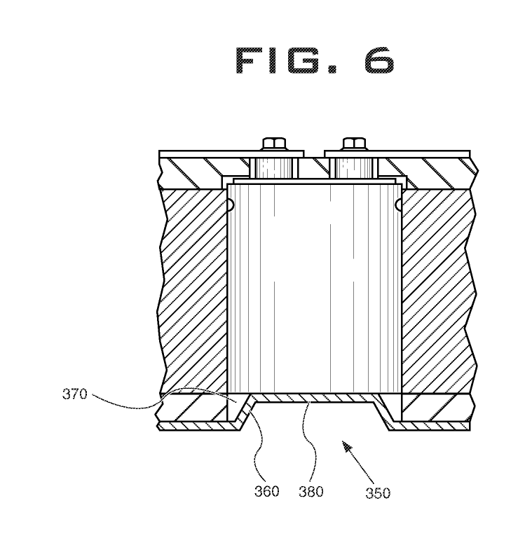

In another example of the current disclosure, the chassis 140 may be generally planar with a matrix of circular dimples 350 formed. Refer to FIG. 5. The rows and columns of the matrix of dimples 350 align with the rows and columns of the matrix of cylindrical voids 340. Referring to FIG. 6, each dimple 350 includes a concave side 360, a convex side 370, and a center portion 380. The convex side 370 of each dimple 350 is oriented toward the side of the chassis 140 supporting the storage cell 30. The center portion 380 of each dimple is generally flat, forming a dimple 350 that is generally frustoconical in cross section. The center portion 380 is sized such that its diameter is the same or less than the diameter of the non-terminal end 50. The dimples 350 in chassis 140 are configured such that they can support the storage cells 30 on the non-terminal end cap 80.

One function of the dimple 350 is to serve as a spring, similar to a Belleville washer, and provide a preload force to hold the storage cell 30 in position. This function will be discussed in more detail in a later section.

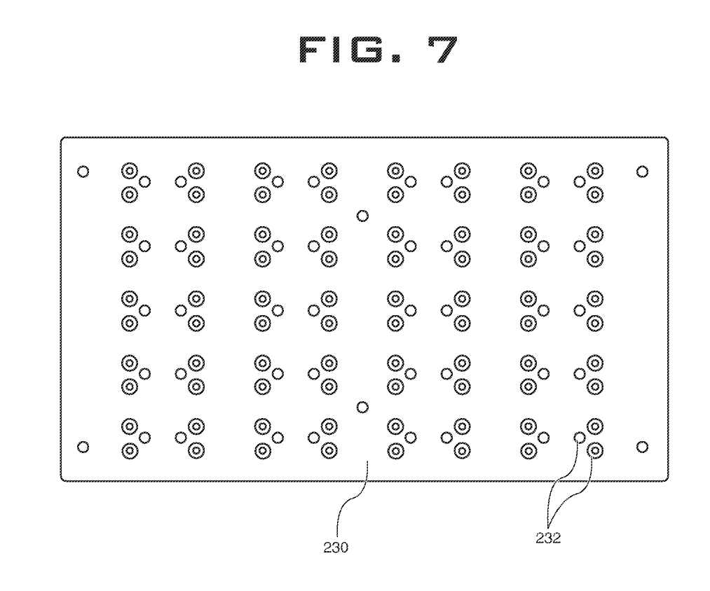

The clamping plate 230 shown in FIG. 7 is configured to prevent axial motion of the storage cells 30 by contacting them on the terminal end cap 70 while the chassis 140 contacts them on the non-terminal end cap 80. The clamping plate 230 is generally planar and similar in dimension to the chassis 140 and the block 330. The clamping plate 230 includes groups of apertures 232 for clearing features of the storage cell 30. Two apertures 232 are configured to clear the connection terminals 60 of the storage cell 30 when the clamping plate 230 is placed over the terminal end 40 of the storage cell 30. Since the connection terminals 60 insert into the apertures 232 and the clamping plate 230 contacts the terminal end cap, rotation of the storage cells 30 is limited. Apertures 232 that are larger than the connection terminals 60 will allow for a certain amount of freedom in placing the storage cells 30. Apertures 232 that are very close to the size of the connection terminals 60 will limit freedom in placing the storage cells 30. It should be appreciated that tight tolerances on the size of the apertures 232 and high precision in placement of the apertures 232 will result in correspondingly high precision on placement and orientation of the storage cells 30. Each group of apertures 232 may contain a third aperture 232. This third aperture 232 is configured to clear vent 120.

Further, the clamping plate 230 may include a recess 234. The recess 234 is configured to accept the terminal end 40 of the storage cells 30. A matrix of recesses 234 is formed in the clamping plate 230. The rows and columns of the matrix of the recesses 234 align with the rows and columns of the matrix of cylindrical voids 340 and the groups of apertures 232. The recess 234 serves to assist the block 330 in limiting radial movement of the storage cells 30. Recesses 234 that are larger than the terminal end 40 will allow for a certain amount of freedom in placing the storage cells 30. Recesses 234 that are very close to the size of the terminal end 40 will limit freedom in placing the storage cells 30.

The clamping plate 230 is configured to limit rotation and axial movement of the storage cells 30. Radial movement of the storage cells 30 is limited by the block 330 of thermally conductive material 310. Secure location of the storage cells 30 allows for robust and repeatable connection of the bus bars 290 to the storage cells 30. Secure location of the storage cells 30 prevents the bus bars 290 from being used to secure the storage cells 30 within the module. The internal structure around the connection terminals 60 functions primarily as an electrical connection and is poorly suited for securing the cells against shock or vibration.

The energy storage module 10 is assembled by first inserting the storage cells 30 into the block 330 of thermally conductive material 310. The storage cells 30 may be inserted individually. Alternatively, the block 330 may be held in a fixture while multiple storage cells 30 are pressed into place at the same time. The storage cells 30 would be properly oriented before being pressed into place. Next, the block 330 holding the storage cells 30 is placed onto the chassis 140. Compression limiters 270 may be added at this time. Next, the clamping plate 230 is placed on top of the block 330. Alignment between the apertures 232 and connection terminals 60 and vent 120 may be verified at this time.

Fasteners 240 are used to secure the clamping plate 230 to the chassis 140. The fasteners 240 are inserted through the block 330 and into an element that accepts the fastener 240. The element could be a blind hole, a through hole, or a weld nut. The blind hole or through hole could be tapped for threads. A threaded nut could also be used to accept the fastener 240. Any washers or spacers needed could also be added at this time. The fasteners 240 are then torqued to a predetermined value. The torque applied to the fasteners 240 applies a compressive force between the chassis 140 and the clamping plate 230. This compressive force secures the storage cells 30 on their non-terminal end 50 and terminal end 40 respectively. The clamping plate 230 is configured such that compression is applied on the perimeter of the terminal end cap 70, but not connection terminals 60.

Compression limiters 270 may be used to limit the compressive force from the fasteners 240. Refer to FIG. 1. The compression limiters consist of a stiff material, usually metal, that is formed into a tube through which the fastener 240 is inserted. The compression limiter 270 may be molded into the block 330, inserted into the block 330, or used outside the block 330. The length of compression limiters 270 may be chosen based upon the tolerance stack up of the chassis 140, clamping plate 230, and storage cell 30. The tolerance of the block 330 may also be considered.

Use of the compression limiter 270 ensures that the storage cells 30 are not crushed or deformed by excessive clamping force. The compression limiter 270 also ensures that clamping force is not applied to the block 330, as the storage cell 30 is typically several millimeters taller than the block. Further, the compression limiter 270 allows more controllable and uniform compression force across the clamping plate 230 since the compressive force is determined by a fixed distance instead of the torque of the fastener 240.

A compliance material 280 may be added between the non-terminal end cap 80 and the chassis 140 during assembly of the energy storage module 10. Refer to FIG. 1. This material serves to preserve the clamping force over time, as the materials and components may relax. The material could be a foam, rubber, composite, or Bakelite. The material could be shaped as an o-ring, disc, washer, or a solid sheet of material.

A cone washer 242 may be the bolted joint formed by fastener 240. The cone washer 242 serves to preserve the clamping force over time, as the materials and components may relax.

Finally, the bus bars 290 and/or printed circuit boards are attached to the connection terminals 60. The bus bars 290 may be attached to external connectors or switchgear at this time.

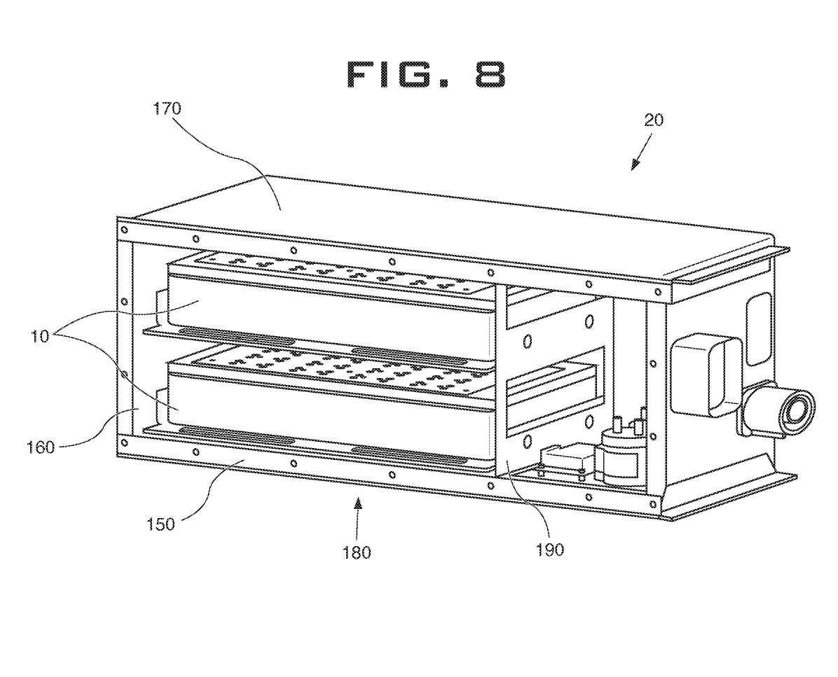

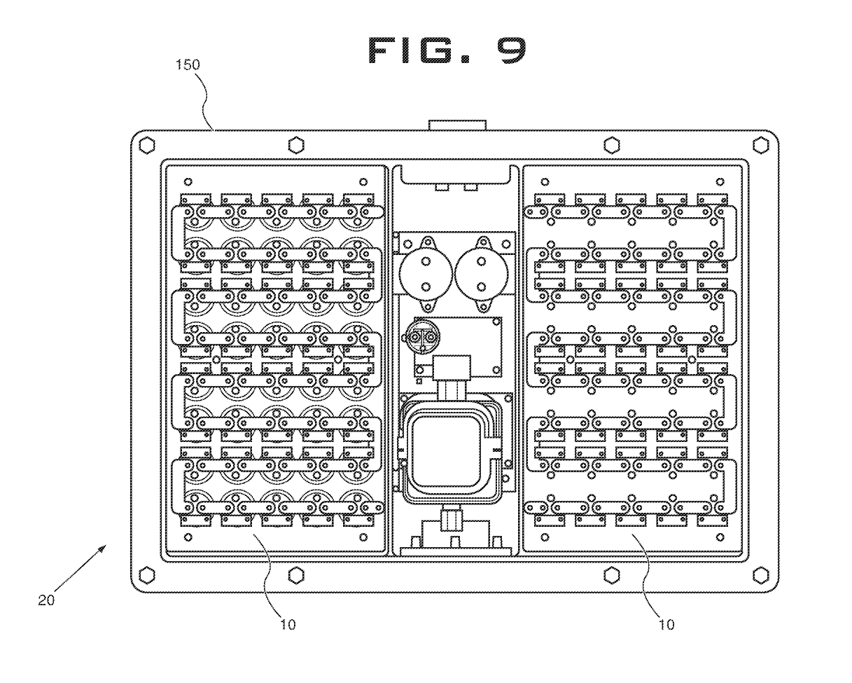

The energy storage module 10 according to this disclosure can be configured to be mounted in an energy storage unit 20. Multiple energy storage modules 10 can be mounted in an energy storage unit 20 and connected together so as to increase voltage or current capacity. The energy storage unit 20 may be enclosed by a housing 150. The housing 150 serves to protect the energy storage module 10 and other components from the environment. The housing 150 includes a housing side 160, a housing top 170, and a housing bottom 180. Multiple energy storage modules 10 can be mounted in many fashions, including vertically as shown in FIG. 8 or horizontally as shown in FIG. 9. The energy storage modules 10 may use mounting provisions on the chassis 140 to mount to a housing side 160, a housing top 170, or a housing bottom 180. The energy storage module 10 may also be mounted to an internal bulkhead 190. Alternatively, the energy storage module 10 may be mounted to both a housing side 160 and an internal bulkhead 190.

### INDUSTRIAL APPLICABILITY

The energy storage module 10 according to the present disclosure is suitable for use in heavy duty applications and harsh environments. The energy storage module 10 is configured with enough storage cells 30 to meet high voltage or high power applications. The clamping plate 230 provides sufficient clamping force on the storage cells 30 to secure them during high shock or vibration experienced in heavy duty applications.

Heavy duty applications may include hybrid vehicles or hybrid machines involved in mining or construction. In hybrid applications, the energy storage module 10 would store energy for use by the vehicle or machine's drivetrain or other electrical system. The energy storage module 10 would be charged by electricity from an engine turning a generator or by electricity generated by dynamic braking. The energy stored would be wasted as heat in non-hybrid applications.

Large amounts of power are charged or discharged into the energy storage module 10, generating large amounts of heat. Some form of cooling should be provided for the storage cells 30 in order to preserve their electrical performance and life expectancy. Thus, a block 330 of thermally conductive material 310 is provided to surround the cells. This material conducts heat away from the cells and serves to equalize the temperature of the individual cells. If a phase change material 320 is used, an additional cooling effect is provided by the melting of the wax material contained within the PCM 320. Still more cooling can be provided by including an active cooling loop 322 within the block 330.

Stationary power generation is another application for the energy storage module 10. In stationary power generator applications, the energy storage package can be used to augment the primary engine and generator. The energy storage module 10 is used to supplement the engine and generator during step power loads to prevent unacceptable amounts of voltage drop.

What is claimed is:

1. An energy storage module for securing a matrix of storage cells, comprising:
a generally planar chassis;
a plurality of generally cylindrical storage cells having;
a terminal end;
a non-terminal end;
two connection terminals located on said terminal end;
a block of thermally conductive material having an array of generally cylindrical voids configured to accept said storage cells;
a generally planar clamping plate having a matrix of apertures configured to accept said connection terminals; and
wherein said storage cells are securely located between said clamping plate on said terminal end and said chassis on said non-terminal end.

2. The energy storage module of claim 1 wherein threaded fasteners are configured to provide a clamping force between said clamping plate and said chassis.

3. The energy storage module of claim 1 wherein the thermally conductive material is a phase change material.

4. The energy storage module of claim 3 wherein said phase change material incorporates an active cooling loop.

5. The energy storage module of claim 1 wherein the generally cylindrical storage cells have a vent in said terminal end; and
said matrix of apertures is further configured to reveal said vent.

6. The energy storage module of claim 2 wherein at least one of the threaded fasteners is inserted through a compression limiter; and
wherein said compression limiter is configured to limit said clamping force to less than a predetermined clamping limit.

7. The energy storage module of claim 1 wherein a compliant material is secured between the non-terminal end of said storage cell and the floor of said housing.

8. The energy storage module of claim 1 wherein the clamping plate is made of a non-conductive material.

9. The energy storage module of claim 1 wherein said clamping plate includes a recess configured to accept the terminal end of said storage cell.

10. The energy storage module of claim 1 wherein the chassis includes a plurality of dimples, each dimple having;
a concave side; and
a convex side including;
a generally flat center portion shaped to engage the non-terminal end of a single said storage cell;

11. The energy storage module of claim 10 wherein the diameter of the center portion is smaller than a diameter of the storage cells.

12. The energy storage module of claim 1 wherein the chassis forms a portion of a housing.

13. An energy storage unit comprising:
a housing including;
a housing top;
a housing bottom vertically opposed from the housing top;
a housing side;
an energy storage module, the energy storage module comprising:
a generally planar chassis;
a plurality of generally cylindrical storage cells having;
a terminal end;
a non-terminal end;
two connection terminals located on said terminal end;
a block of thermally conductive material having an array of generally cylindrical voids configured to accept said storage cells;
a generally planar clamping plate having a matrix of apertures configured to accept said connection terminals;
wherein said storage cells are securely located between said clamping plate on said terminal end and said chassis on said non-terminal end; and
wherein the chassis of said energy storage module is secured to the housing.

14. The energy storage unit of claim 13 wherein the thermally conductive material is a phase change material.

15. The energy storage unit of claim 14 wherein said phase change material incorporates an active cooling loop.

16. The energy storage unit of claim 13 wherein the chassis of said energy storage module is secured to said housing side.

17. The energy storage unit of claim 13 wherein the chassis of said energy storage module is secured to said housing side and an internal bulkhead.

18. The energy storage unit of claim 13 wherein the chassis of said energy storage module is secured to a housing floor.

19. The energy storage unit of claim 13 wherein two or more energy storage modules are secured to the housing, the energy storage modules being arranged vertically.

20. The energy storage unit of claim 13 wherein two or more energy storage modules are secured to the housing, the energy storage modules being arranged horizontally.
